(19) United States
(12) Patent Application Publication
(10) Pub. No.: US 2010/0013967 A1
(43) Pub. Date: Jan. 21, 2010

(54) SOLID STATE IMAGING DEVICE

(75) Inventor: Makoto Tanaka, Kanagawa (JP)

Correspondence Address: YOUNG & THOMPSON, 209 Madison Street, Suite 500, Alexandria, VA, 22314, US

(73) Assignee: NEC Electronics Corporation, Kanagawa (JP)

(21) Appl. No.: 12/496,050

(22) Filed: Jul. 1, 2009

(30) Foreign Application Priority Data
Jul. 18, 2008 (JP) 2008-187714

(51) Int. Cl. H04N 5/335; H01L 31/18

(52) U.S. Cl. 348/273; 438/75; 348/294; 257/E21.158; 348/E05.091

(57) ABSTRACT

A solid state imaging device includes: a light receiving portion; a transfer gate; a clock wiring group; and a substance. The light receiving portion includes a plurality of light receiving elements formed on a substrate. The charge transfer portion transfers electric charges supplied from the light receiving portion. The transfer gate is provided between the light receiving portion and the charge transfer portion and supplies the electric charges accumulated in the light receiving portion to the charge transfer portion. The clock wiring group includes a plurality of wirings and supplies a plurality of clocks for transferring the electric charges. The substance shields light with a wavelength lower than a predetermined wavelength. The plurality of wirings is arranged away from one another with a gap corresponding to the predetermined wavelength. The substance is arranged to cover the gap and shields light with a wavelength possibly passing through the gap.

### INCORPORATION BY REFERENCE

This application is based upon and claims the benefit of priority from Japanese patent application No. 2008-187714 filed on Jul. 1, 2008, the disclosure of which is incorporated herein in its entirety by reference.

### BACKGROUND OF THE INVENTION

1. Field of the Invention

The present invention relates to a solid state imaging device.

2. Description of Related Art

Electronic devices (e.g., a digital camera and a camera-equipped mobile phone) having a solid state imaging device have become popular. The solid state imaging device includes a light receiving portion that converts light into electric charges and a charge transfer portion that transfers the electric charges supplied from the light receiving portion to an output portion. The light receiving portion includes a light receiving element (photoelectric conversion element), such as a photodiode, converting light into electric charges.

A failure such as smear (a phenomenon of highlight clipping or over exposure) often occurs to a solid state imaging device including a charge coupled device (CCD) when a subject brighter than surroundings is imaged. Such a failure derives from generation of electric charges as a result of striking of light against surrounding portions other than the photodiodes (such as a signal line or a vertical transfer CCD element) or mixture of electric charges generated within a semiconductor substrate into a transfer path of original signal charges.

If a signal from the photodiode to a charge detecting portion in a normal state is converted into the number of electrons, the number of electrons is as small as two or three to several tens of thousands. Due to this, aliasing resulting from the electric charges generated by light leaking into this portion (portion ranging from the photodiode to the charge detecting portion) causes a decrease in an S/N ratio.

To reduce the aliasing resulting from the leaking light is important so as to improve the S/N ratio. Due to this, there is known a technique for shielding or shading light to prevent light incident on a location other than a photodiode from reaching a semiconductor substrate (for example, Japanese Laid-Open Patent Application JP-P 2005-209674A).

FIG. 1 is a block diagram showing a configuration of a charge transfer device 100 described in JP-P 2005-209674A. Referring to FIG. 1, the charge transfer device 100 includes a second conduction type channel layer, and transfer electrodes 152 and 153. Here, the second conduction type channel layer is opposite in conduction type to a first conduction type and serves as a charge transfer region 130 formed in a first conduct ion type semiconductor substrate. The transfer electrodes 152 and 153 are arranged on the channel layer via an insulating film and transfer electric charges. The charge transfer device 100 also includes wirings 155 and 156 formed above the transfer electrodes 152 and 153 to cross the transfer electrodes 152 and 153 in three dimensions. In a plan view, the charge transfer device 100 is configured so that an opening 159 formed by a gap between the transfer electrodes 152 and 153 and a gap between the wirings 155 and 156 on the charge transfer region 130 has a length equal to or smaller than 0.2 micrometer (μm) in every direction. As can be seen, according to the technique disclosed in JP-P 2005-209674A, a wiring interval is set as short as 0.2 μm, thereby shielding or shading light based on principle of diffraction.

However, we have now discovered the following facts. For light shielding or shading based on the principle of diffraction, it is necessary to perform micro wiring processing to set a wiring interval to 0.2 μm. This micro wiring processing disadvantageously makes a manufacturing process complicated. This complicated or advanced manufacturing process often disadvantageously pushes up manufacturing cost and makes a manufacturing period long.

Moreover, since the wiring interval is equal to or shorter than 0.2 μm, a parasitic capacitance increases. This parasitic capacitance often disadvantageously causes a signal delay.

### SUMMARY

The present invention seeks to solve one or more of the above problems, or to improve upon those problems at least in portion.

One object of the present invention is to provide a technique for appropriately shielding or shading light without depending on a reduction in a wiring interval.

In one embodiment of the present invention, a solid state imaging device includes: a light receiving portion configured to include a plurality of light receiving elements formed on a substrate; a charge transfer portion configured to transfer electric charges supplied from the light receiving portion; a transfer gate configured to be provided between the light receiving portion and the charge transfer portion and supply the electric charges accumulated in the light receiving portion to the charge transfer portion; a clock wiring group configured include a plurality of wirings and supply a plurality of clocks for transferring the electric charges; and a substance configured to shield light with a wavelength lower than a predetermined wavelength, wherein the plurality of wirings is arranged away from one another with a gap corresponding to the predetermined wavelength, wherein the substance is arranged to cover the gap and shields light with a wavelength possibly passing through the gap.

In another embodiment of the present invention, a method of manufacturing a solid state imaging device, wherein the solid state imaging device includes: a light receiving portion configured to include a plurality of light receiving elements formed on a substrate, a charge transfer portion configured to transfer electric charges supplied from the light receiving portion, a transfer gate configured to be provided between the light receiving portion and the charge transfer portion and supply the electric charges accumulated in the light receiving portion to the charge transfer portion, and a clock wiring group configured to include a plurality of wirings and supply a plurality of clocks for transferring the electric charges, the method includes: arranging the plurality of wirings away from one another with a gap corresponding to a predetermined wavelength; and arranging a substance capable of shielding light with a wavelength lower than the predetermined wavelength to cover the gap, wherein the step of arranging the plurality of wirings, includes: producing a plurality of transfer clock wirings which supplies a plurality of transfer clocks to the charge transfer portion, producing a read clock wiring which supplies a read clock to the transfer gate, producing a first upper layer wiring which is provided in an upper layer arranged on the plurality of transfer clock wirings and extended in a first direction, and producing a second upper layer wiring which is provided in the upper layer and extended along with the first upper layer wiring with a first gap therebetween, wherein the step of producing the plurality of transfer clock wirings, includes: producing a first clock wiring which is extended in a second direction perpendicular to the first direction and supplies a first clock to the charge transfer portion, and producing a second clock wiring which is extended in the second direction along with the first clock wiring with a second gap therebetween and supplies a second clock to the charge transfer portion, wherein the step of producing the read clock wiring, includes: producing the read clock wiring which is extended in the second direction and provided in parallel to the first clock wiring with a third gap therebetween, and wherein the step of arranging the substance, includes: forming the substance as at least one of the transfer gate electrode and the read gate electrode.

According to the present invention, it is possible to configure a solid state imaging device capable of appropriately shielding or shading light in regions other than a light receiving portion without depending on a reduction in a wiring interval.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram showing a configuration of a charge transfer device described in JP-P 2005-209674A;

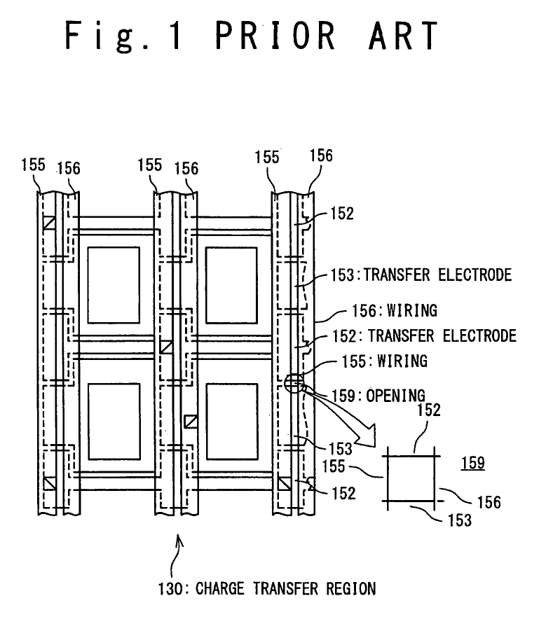

FIG. 2 is a plan view showing an example of a configuration of a solid state imaging device according to the present embodiment;

FIG. 3 is a plan view showing an example of a configuration of the solid state imaging device according to the present embodiment excluding wirings;

FIG. 4 is a plan view showing an example of a configuration of the solid state imaging device 1 excluding a first upper layer wiring and a second upper layer wiring;

FIG. 5 is a cross-sectional view showing an example of a configuration of the solid state imaging device 1 taken along a line A-A′ shown in FIG. 2;

FIG. 6 is a cross-sectional view showing an example of a configuration of the solid state imaging device 1 taken along a line B-B′ shown in FIG. 2;

FIG. 7 is a cross-sectional view showing an example of a configuration of the solid state imaging device 1 taken along a line C-C′ shown in FIG. 2;

FIG. 8 is a cross-sectional view showing an example of a configuration of the solid state imaging device 1 taken along a line D-D′ shown in FIG. 2;

FIG. 9 is a cross-sectional view showing an example of a configuration of the solid state imaging device 1 taken along a line E-E′ shown in FIG. 2;

FIG. 10 is a cross-sectional view showing an example of a configuration of the solid state imaging device 1 taken along a line F-F′ shown in FIG. 2;

FIG. 11 is a cross-sectional view showing an example of a configuration of the solid state imaging device 1 taken along a line G-G′ shown in FIG. 2; and

FIG. 12 is a cross-sectional view showing an example of a configuration of the solid state imaging device including a substance that absorbs a shorter-wavelength light on a grating structure absorbing a longer-wavelength light.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

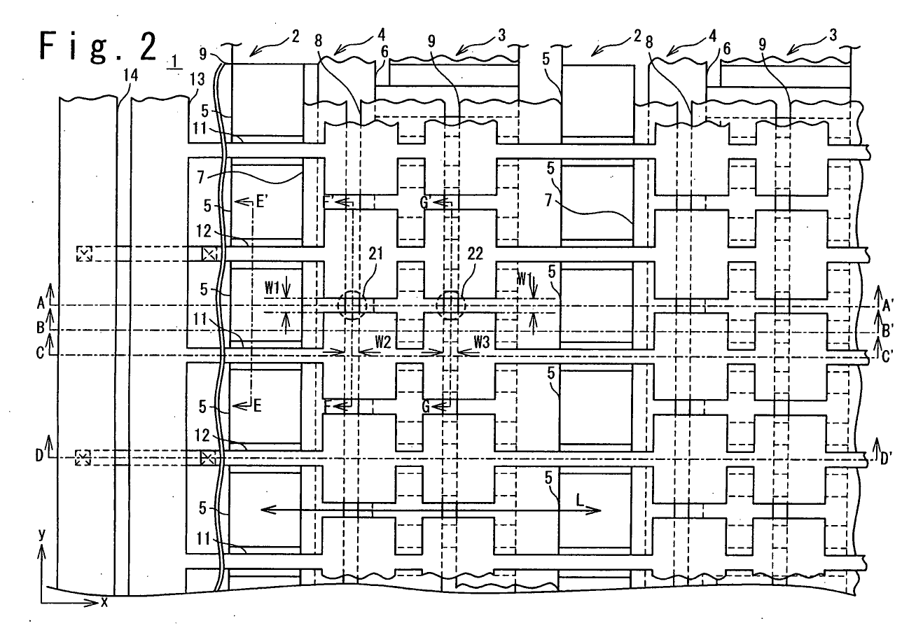

Embodiments of the present invention will be described hereinafter based on the drawings. FIG. 2 is a plan view showing an example of a configuration of a solid state imaging device 1 according to an embodiment of the present invention. The solid state imaging device 1 according to the present embodiment includes a CCD image sensor. Generally, the CCD image sensor includes photodiode columns in which a plurality of photodiodes are arranged in columns, registers transferring signal charges and transfer gates transferring the signal charges from the photodiodes to the registers.

Each of the plurality of photodiodes includes a photo-electric conversion function that reacts to incident light and generates electric charges by photoelectric conversion and a charge accumulation function that temporarily accumulates the electric charges in the photodiode. The accumulated electric charges are transferred to the register via the transfer gate. The electric charges transferred to the register are sequentially transmitted to a charge detecting portion. The charge detecting portion converts the received electric charges into a voltage and outputs the voltage from an amplifier.

Referring to FIG. 2, the solid state imaging device 1 includes a light receiving portion 2, a charge transfer portion 3 and a transfer gate 4. The solid state imaging device 1 also includes a first bus line 13 and a second bus line 14. The light receiving portion 2 includes a plurality of photodiodes 5. The plurality of photodiodes 5 is arranged so that a distance between the adjacent photodiodes 5 is L. In this embodiment described below, the plurality of photodiodes 5 arranged along a y-axis direction based on a coordinate axis of FIG. 2 is referred to as “a photodiode column”.

A gate electrode 6 is arranged on the transfer gate 4. A read clock wiring 7 constituted by a metal wiring is arranged on the gate electrode 6. The read clock wiring 7 is connected to the gate electrode 6 arranged on the transfer gate 4 and supplies a read clock FTG to the gate electrode 6.

The charge transfer portion 3 includes a plurality of transfer gate electrodes and a plurality of barrier gate electrodes. Moreover, as shown in FIG. 2, a first transfer clock wiring 8 and a second transfer clock wiring 9 each constituted by a metal wiring are arranged on the plurality of transfer gate electrodes and the plurality of barrier gate electrodes of the charge transfer portion 3. Each of the first transfer clock wiring 8 and the second transfer clock wiring 9 is connected to corresponding electrodes among the plurality of transfer gate electrodes and the plurality of barrier gate electrodes.

A first upper layer wiring 11 and a second upper layer wiring 12 are arranged on the read clock wiring 7, the first transfer clock wiring 8 and the second transfer clock wiring 9. The first upper layer wiring 11 is connected to the first transfer clock wiring 8 and supplies a signal (hereinafter, “first clock F1”) for driving the register of the charge transfer portion 3 to the first transfer clock wiring 8. The second upper layer wiring 12 is connected to the second transfer clock wiring 9 and supplies a signal (hereinafter, “second clock F2”) for driving the register of the charge transfer portion 3 to the second transfer clock wiring 9.

The light receiving portion 2 includes a plurality of photodiode columns. The plurality of photodiode columns is provided to be spatially away from one another. Due to this, signals outputted from the plurality of photodiode columns simultaneously are information spatially away from one another. The solid state imaging device 1 compensates positions of the spatially away information using a position compensation memory (not shown) provided outside.

If a center distance L between sensors of the adjacent photodiode columns (hereinafter, “line interval”) becomes long, an information amount necessary for position compensation processing increases. That is, the solid state imaging device 1 having a long line interval requires a large memory capacity. To reduce the memory capacity and cut down system cost of the solid state imaging device 1, it is preferable to form the solid state imaging device having a narrow line interval.

A capacity of the register of the charge transfer portion 3 is as large as several hundreds to several thousands of pico-Farads (pF). To cause the charge transfer portion 3 having a large load capacity to operate at high speed, it is preferable to make the first transfer clock wiring 8 and the second transfer clock wiring 9 thick wirings having low parasitic resistances. However, in the solid state imaging device 1 having a narrow line interval according to the present embodiment, it is difficult to arrange thick wirings having low parasitic resistances among the registers and the photodiodes. In other words, in the solid state imaging device 1 having the narrow line interval, there is a limit to widths of the first transfer clock wiring 8 and the second transfer clock wiring 9.

That is why the thick wirings called “bus lines” (first bus line 13 and second bus line 14) are provided in the solid state imaging device 1 according to the present embodiment. As shown in FIG. 2, the solid state imaging device 1 includes the first bus line 13 and the second bus line 14 arranged in or outside of the light receiving portion 2. In the solid state imaging device 1 according to the present embodiment, a wiring width of each of the bus lines is preferably, for example, several tens to several hundreds of micrometers (μm).

The first bus line 13 supplies the signal (first clock F1) for causing the charge transfer portion 3 to operate at high speed to the first upper layer wiring 11. The second bus line 14 supplies the signal (second clock F2) for causing the charge transfer portion 3 to operate at high speed to the second upper layer wiring 12. The first bus line 13 supplies the first clock F1 to the first transfer clock wiring 8 via the first upper wiring 11 to thereby supply the first clock F1 to the charge transfer portion 3. The second bus line 14 supplies the second clock F2 to the second transfer clock wiring 9 via the second upper wiring 12 to thereby supply the second clock F2 to the charge transfer portion 3. Generally, the first clock F1 and the second clock F2 are different from each other and opposite in phase. Due to this, the first upper layer wiring 11 and the second upper layer wiring 12 are arranged at a certain interval (a first width W1) kept therebetween. Furthermore, the first transfer clock wiring 8 and the second transfer clock wiring 9 are arranged at a certain interval (a third width W3) kept therebetween.

In other words, the first upper wiring 11 and the second upper wiring 12 are adjacent to each other at the first width W1 therebetween. Further, the read clock wiring 7 and the first transfer clock wiring 8 are adjacent to each other at a second width W2 therebetween. Moreover, the first transfer clock wiring 8 and the second transfer clock wiring 9 are adjacent to each other at the third width W3 therebetween. In the solid state imaging device 1, a first gap region 21 and a second gap region 22 are thereby provided.

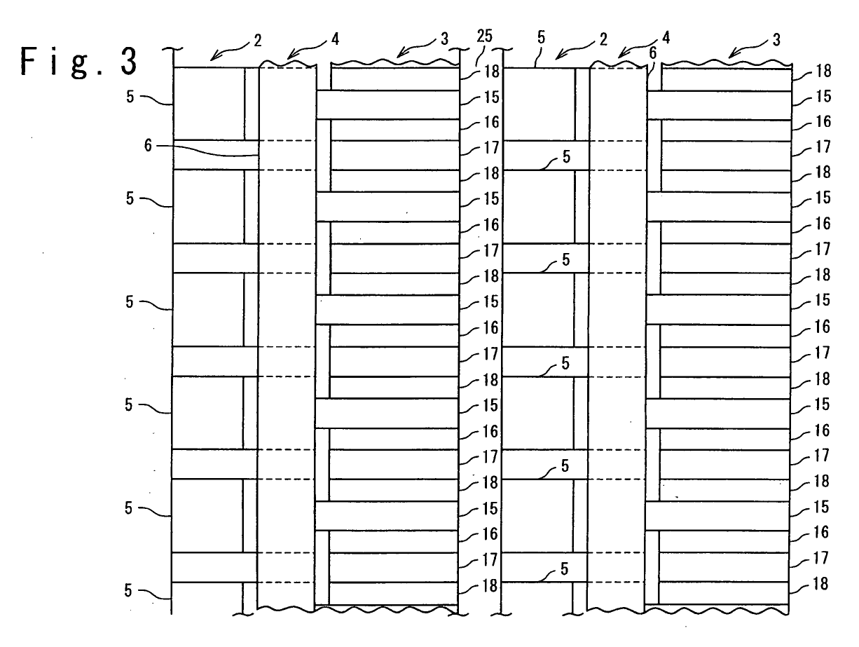

FIG. 3 is a plan view showing an example of configurations of the light receiving portion 2, the charge transfer portion 3 and the transfer gate 4 when the wirings are excluded from the solid state imaging device 1. The light receiving portion 2 includes the plurality of photodiodes 5 provided on a substrate. The plurality of photodiodes 5 is arranged independently of one another. The charge transfer portion 3 includes a plurality of first transfer gate electrodes 15, a plurality of first barrier gate electrodes 16, a plurality of second transfer gate electrodes 17 and a plurality of second barrier gate electrodes 18. A barrier 25 is provided between the two photodiode columns. The plurality of first transfer gate electrodes 15 and the plurality of first barrier gate electrodes 16 are connected to the first transfer clock wiring 8. The plurality of second transfer gate electrodes 17 and the plurality of second barrier gate electrodes 18 are connected to the second transfer clock wiring 9.

The transfer gate 4 is separately formed between the plurality of photodiodes 5 and the charge transfer portion 3, respectively. The transfer gate 4 includes a channel region provided on the substrate and the gate electrode 6 arranged on the channel region. Electric charges accumulated in each photodiode 5 are transferred to the charge transfer portion 3 by an on-operation of the transfer gate 4.

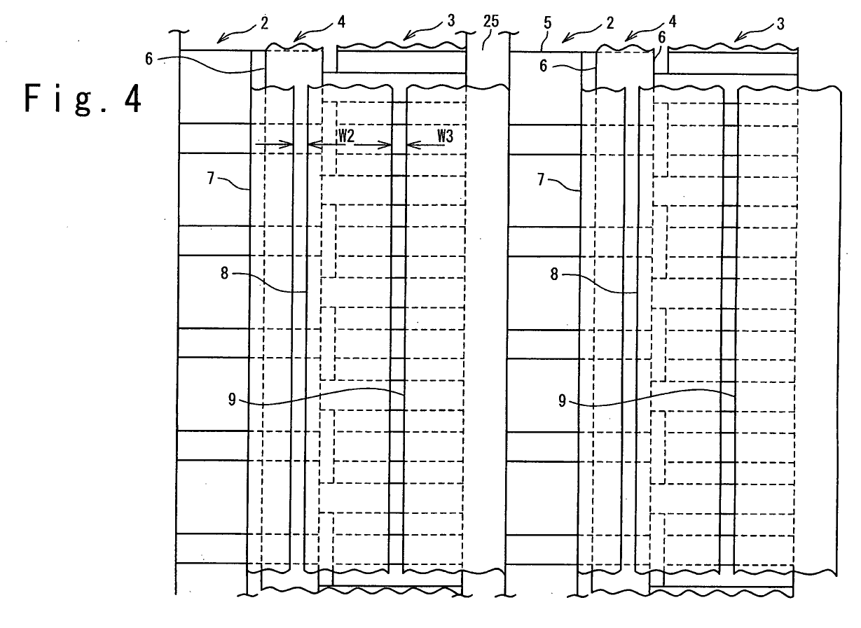

FIG. 4 is a plan view showing an example of a configuration of the solid state imaging device 1 excluding the first upper layer wiring 11 and the second upper layer wiring 12. The read clock wiring 7, the first transfer clock wiring 8 and the second transfer clock wiring 9 are arranged in parallel to the transfer gate 4. The second width W2 between the read clock wiring 7 and the first transfer clock wiring 8 is provided on the gate electrode 6. The third width W3 between the first transfer clock wiring 8 and the second transfer clock wiring 9 is provided on the first transfer gate electrodes 15, the first barrier gate electrodes 16, the second transfer gate electrodes 17 and the second barrier gate electrodes 18.

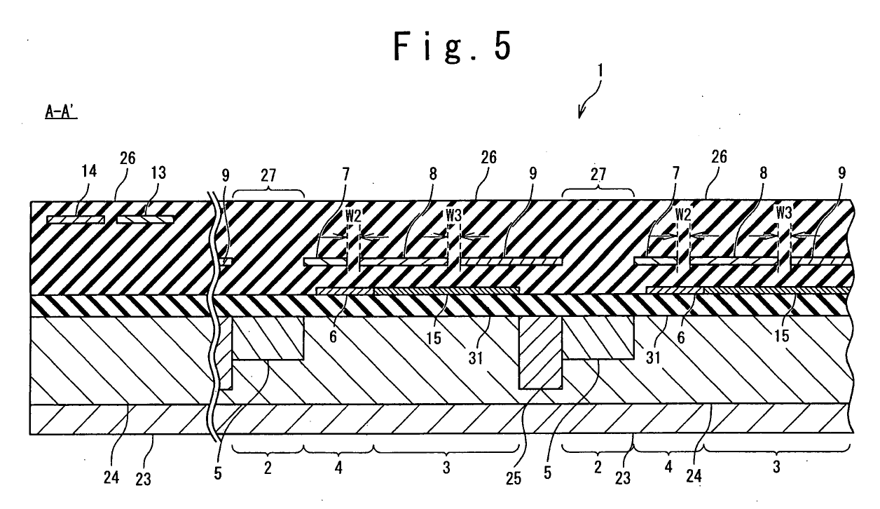

FIG. 5 is a cross-sectional view showing an example of a configuration of the solid state imaging device 1 along the line A-A′ exemplarily shown in FIG. 2. As shown in FIG. 5, the solid state imaging device 1 includes a well 24 provided in a semiconductor substrate 23. The photodiode 5 of the solid state imaging device 1 are formed in the well 24. A transmission region 27 is provided on each photodiode 5. The gate electrode 6 is provided below the read clock wiring 7 and the first transfer clock wiring 8. The gate electrode 6 is provided at a position so as to shield or shade light passing through the first width W1 and then the second width W2 for preventing the light from reaching the well 24.

The first transfer gate electrodes 15, the first barrier gate electrodes 16, the second transfer gate electrodes 17 and the second barrier gate electrodes 18 are provided below the first transfer clock wiring 8 and the second transfer clock wiring 9. The first transfer gate electrodes 15, the first barrier gate electrodes 16, the second transfer gate electrodes 17 and the second barrier gate electrodes 18 are provided at positions so as to shield or shade light passing through the second width W2 and then third width W3 for preventing the light from reaching the well 24. For example, as shown in FIG. 5, in the A-A′ cross section, the first transfer gate electrode 15 shields or shades light passing through the second width W2 and then the third width W3.

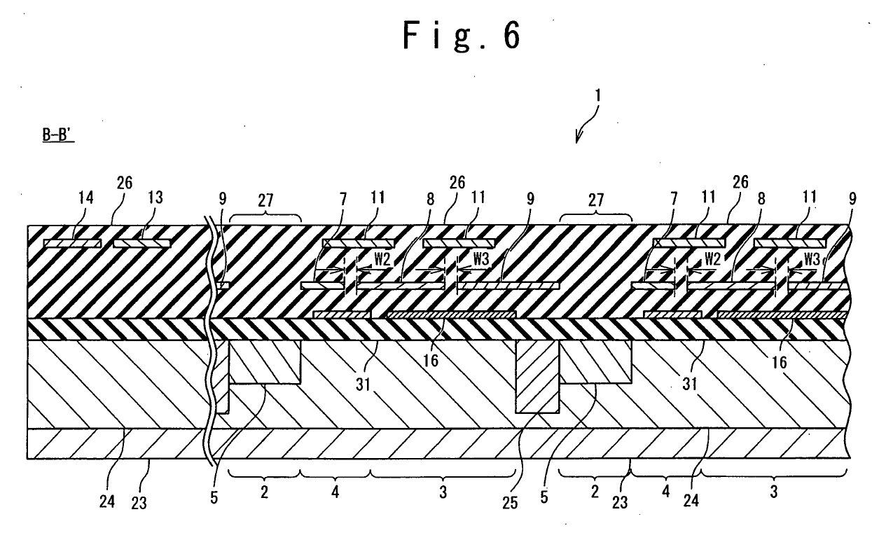

FIG. 6 is a cross-sectional view showing a configuration of the solid state imaging device 1 along the line B-B′ exemplarily shown in FIG. 2. In the B-B′ cross section, the first upper layer wiring 11 is provided above the read clock wiring 7, the first transfer clock wiring 8 and the second transfer clock wiring 9. As shown in FIG. 6, in the B-B′ cross section, the first upper layer wiring 11 is arranged above the first width W1, the second width W2 and the third width W3. The first upper layer wiring 11 shields or shades light from reaching the well 24.

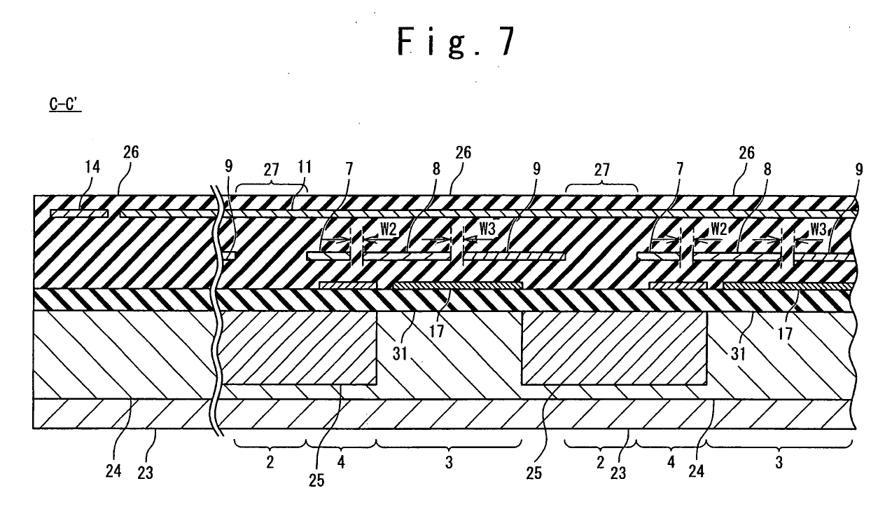

FIG. 7 is a cross-sectional view showing a configuration of the solid state imaging device 1 along the line C-C′ exemplarily shown in FIG. 2. In the C-C′ cross section, the first upper layer wiring 11 is provided above the read clock wiring 7, the first transfer clock wiring 8 and the second transfer clock wiring 9. The first upper layer wiring 11 is connected to the first bus line 13. As shown in FIG. 7, in the C-C′ cross section, the first upper layer wiring 11 is arranged above the first width W1, the second width W2 and the third width W3. The first upper layer wiring 11 shields or shades light from reaching the well 24.

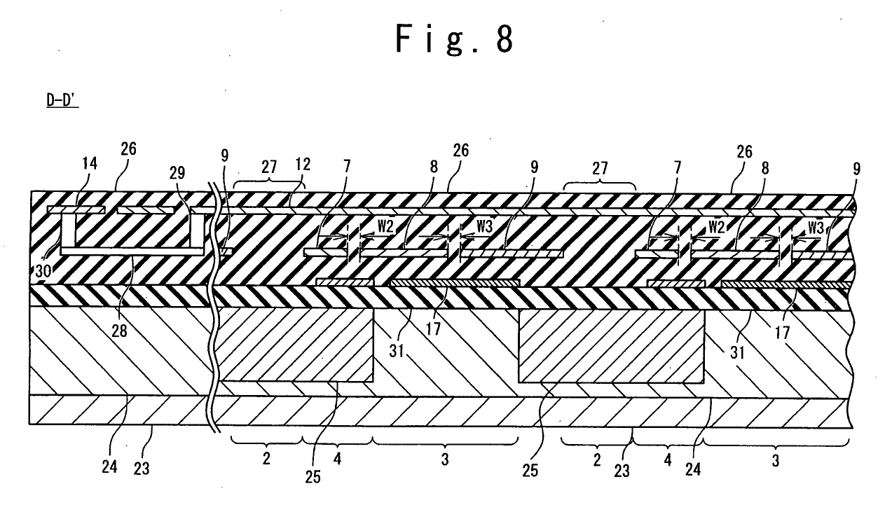

FIG. 8 is a cross-sectional view showing a configuration of the solid state imaging device 1 along the line D-D′ exemplarily shown in FIG. 2. In the D-D′ cross section, the second upper layer wiring 12 is provided above the read clock wiring 7, the first transfer clock wiring 8 and the second transfer clock wiring 9. The second upper layer wiring 12 is connected to a wiring 28 via a first via 29. The wiring 28 is connected to the second bus line 14 via a second via 30. As shown in FIG. 8, in the D-D′ cross section, the second upper layer wiring 12 is arranged above the first width W1, the second width W2 and the third width W3. The second upper layer wiring 12 shields or shades light from reaching the well 24.

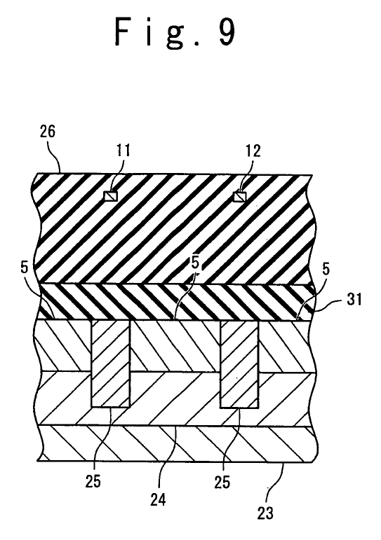

FIG. 9 is a cross-sectional view showing a configuration of the solid state imaging device 1 along the line E-E′ exemplarily shown in FIG. 2. As shown in FIG. 9, in the E-E′ cross section, the first upper layer wiring 11 and the second upper layer wiring 12 are arranged across the transmission region 27. Each of the upper layer wiring 11 and the second upper layer wiring 12 is arranged so as not to shield or shade light incident on the photodiodes 5.

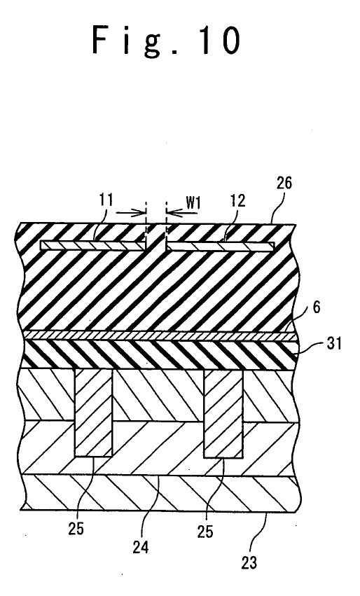

FIG. 10 is a cross-sectional view showing a configuration of the solid state imaging device 1 along the line F-F′ exemplarily shown in FIG. 2. As shown in FIG. 10, in the F-F′ cross section, the first upper layer wiring 11 and the second upper layer wiring 12 are arranged to have the first width W1 therebetween. The gate electrode 6 is provided below the first upper layer wiring 11 and the second upper layer wiring 12. The gate electrode 6 is provided to shield or shade light passing through the first width W1 and the second width W2.

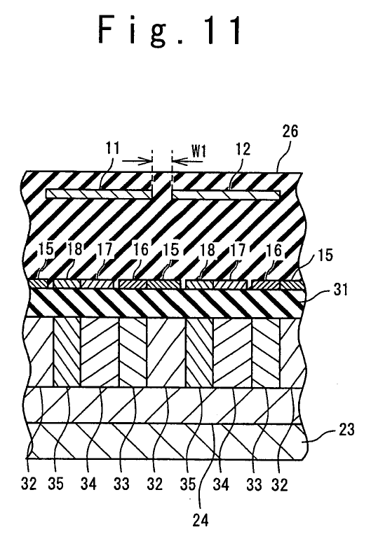

FIG. 11 is a cross-sectional view showing a configuration of the solid state imaging device 1 along the line G-G′ exemplarily shown in FIG. 2. As shown in FIG. 11, in the G-G′ cross section, the first upper layer wiring 11 and the second upper layer wiring 12 are arranged to have the first width W1 therebetween. The first transfer gate electrodes 15, the first barrier gate electrodes 16, the second transfer gate electrodes 17 and the second barrier gate electrodes 18 are provided below the first upper layer wiring 11 and the second upper layer wiring 12. Furthermore, in the G-G′ cross section, first storage regions 32, first barrier regions 33, second storage regions 34 and second barrier regions 35 are provided in the well 24. The first transfer gate electrodes 15, the first barrier gate electrodes 16, the second transfer gate electrodes 17 and the second barrier gate electrodes 18 are arranged between the substrate and a gap constituted by the first width W1 and the third width W3, and shield or shade light passing through the first width W1 and the third width W3.

As stated above, in the solid state imaging device 1 according to the present embodiment, the gaps (the first gap region 21 and the second gap region 22) surrounded by the first upper layer wiring 11, the second upper layer wiring 12, the read clock wiring 7 and the first transfer clock wiring 8 are formed. If the gaps formed are narrower than a wavelength of light, it is difficult to transmit the light having the wavelength larger than a predetermined wavelength (hereinafter, “longer-wavelength light”) through the gaps by diffraction limit. Accordingly, by making the first gap region 21 or the second gap region 22 narrower, the solid state imaging device 1 according to the present embodiment can shield or shade the longer-wavelength light corresponding to a width of the first gap region 21 or the second gap region 22 based on the principle of the diffraction limit.

Normally, if the wavelength of the light is equal to or smaller than 1100 nanometers (nm), each silicon photodiode provided in the light receiving portion 2 can obtain electric charges by the photoelectric conversion. Further, the wavelength of visible light (λ: 380 nm to 780 nm) is smaller than the wavelength equal to or smaller than 1100 nm. Therefore, the solid state imaging device 1 can be appropriately actuated by suppressing the light having above-mentioned wavelength from being incident on regions other than the light receiving portion 2.

In the case where the solid state imaging device 1 according to the present embodiment is to be manufactured at low cost, it is preferable that the width of the first gap region 21 or the second gap region 22 is about 0.2 μm to 0.4 μm (200 nm to 400 nm). In the case where the width is, for example, 0.4 μm, the solid state imaging device 1 cuts off visible light (or infrared) having the wavelength equal to or larger than 400 nm in the first gap region 21 or the second gap region 22 as the longer-wavelength light.

If the first gap region 21 or the second gap region 22 shields or shades the light having the wavelength equal to or larger than 400 nm, the wavelength of the light (hereinafter “shorter-wavelength light”) passing through the first gap region 21 or the second gap region 22 without being cut off is smaller than the wavelength (equal to or larger than 400 nm) of the cut-off light. The shorter-wavelength light is transmitted through the first gap region 21 or the second gap region 22 with being hardly attenuated.

The solid state imaging device 1 according to the present embodiment includes the gate electrode (gate electrode 6) below the first gap region 21. Likewise, the solid state imaging device 1 according to the present embodiment includes the gate electrode (first transfer gate electrode 15) below the second gap region 22. The gate electrode arranged below the first gap region 21 or the second gap region 22 is composed of a substance or material that absorbs or attenuates light. The substance or material absorbs shorter-wavelength light at a shallow position from the light receiving surface.

In the solid state imaging device 1, the gate electrode absorbs the shorter-wavelength light passing through the first gap region 21 or the second gap region 22 without being cut off. Since there is no need to shield or shade the light, which has the wavelength inducing generation of electric charges, only by using the first gap region 21 or the second gap region 22, the widths (first width W1, second width W2 and third width W3) can be set up to about 0.4 μm. It is to be noted that polysilicon is an ordinary constituent element used as an electrode portion of the register. It is, therefore, possible to constitute the solid state imaging device 1 according to the present embodiment without newly adding the polysilicon as a constituent element for absorbing the shorter-wavelength light.

Moreover, the solid state imaging device 1 according to the present embodiment separately absorbs the longer-wavelength light and the shorter-wavelength light. It suffices that the first gap region 21 and the second gap region 22 are provided at intervals that can absorb the longer-wavelength light. In addition, the first gap region 21 and the second gap region 22 are constituted without need to consider shielding the shorter-wavelength light. Therefore, the limit to the gap interval can be relaxed. That is, since the gap between the wirings can be set wide, a parasitic resistance between the wirings can be reduced.

Furthermore, the solid state imaging device 1 according to the present embodiment does not include a dedicated metal film covering the regions other than the light receiving portion 2. Due to this, a parasitic capacity resulting from the metal film can be reduced. Besides, since the solid state imaging device 1 according to the present embodiment does not include a metal film for light shielding, it is possible to suppress an increase in the number of steps in a manufacturing process for the solid state imaging device 1. Further, by employing a layer where a light shielding metal film is possibly provided as a wiring, complicated wirings can be created.

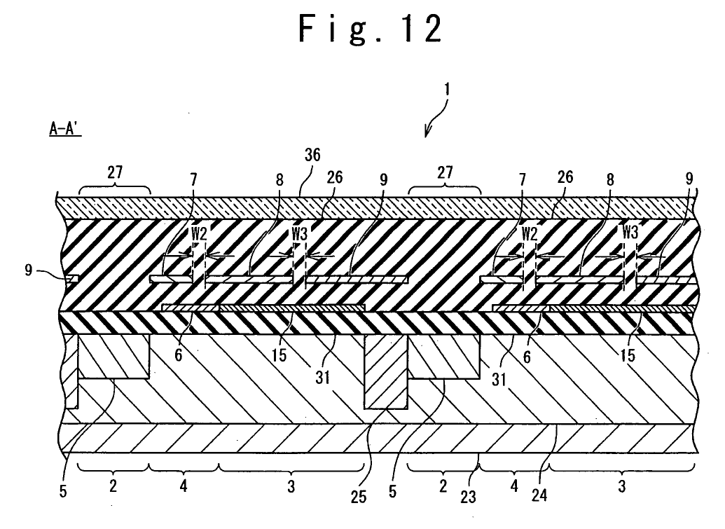

In the above-stated embodiment, the solid state imaging device 1 may include a structure composed of a substance or material that absorbs the shorter-wavelength light on a grating structure (the first gap region 21 and the second gap region 22) that absorbs the longer-wavelength light. FIG. 12 is a cross-sectional view showing an example of a configuration of the solid state imaging device 1 that includes the substance or material (primary color filter 36) that absorbs the shorter-wavelength light on the substance or material that absorbs the longer-wavelength light. In this case, the solid state imaging device 1 shields light by absorbing the longer-wavelength light using the gaps between the wirings after absorbing the shorter-wavelength light.

If such the solid state imaging device 1 is to be manufactured by an ordinary manufacturing process, a step of forming polysilicon on a metal film is not often executed. In that case, a material other than polysilicon is preferably used as the substance or material that absorbs the shorter-wavelength light. As shown in FIG. 12, filters 36 of three primary colors of R, G and B are used for decomposing light in a primary color CCD. Among those three primary color filters 36, the R filter that does not transmit shorter-wavelength light is arranged at a position above the first gap region 21 and the second gap region 22, the solid state imaging device 1 shown in FIG. 12 can be formed without newly adding a step of forming a polysilicon film.

In the case where a gap is present between the metal wirings and the gate electrodes 6, the transfer gate electrodes (first transfer gate electrodes 15 to the second barrier gate electrodes 18) or the like are not formed at a location of the gap, the structure that absorbs the shorter-wavelength light is provided at the location, the above-stated advantages can be obtained. In the solid state imaging device 1 according to the present embodiment, it suffices to arrange the structure that absorbs the shorter-wavelength light either above or below the location of the gap. As can be understood, design limitation is relaxed in the solid state imaging device 1 according to the present embodiment.

In the embodiment described above, the solid state imaging device 1 operating according to the first clock F1 and the second clock F2 is exemplarily shown so as to easily understand the present invention. However, this configuration is not intended to limit the solid state imaging device 1 according to the present invention. Similar advantages can be obtained even if the present invention is applied to the constitution of the solid state imaging device 1 operating according to, for example, four-phase clocks (F1 to F4).

It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A solid state imaging device comprising:
a light receiving portion configured to include a plurality of light receiving elements formed on a substrate;
a charge transfer portion configured to transfer electric charges supplied from said light receiving portion;
a transfer gate configured to be provided between said light receiving portion and said charge transfer portion and supply said electric charges accumulated in said light receiving portion to said charge transfer portion;
a clock wiring group configured include a plurality of wirings and supply a plurality of clocks for transferring said electric charges; and
a substance configured to shield light with a wavelength lower than a predetermined wavelength,
wherein said plurality of wirings is arranged away from one another with a gap corresponding to said predetermined wavelength,
wherein said substance is arranged to cover said gap and shields light with a wavelength possibly passing through said gap.

2. The solid state imaging device according to claim 1, wherein said clock wiring group includes:
a plurality of transfer clock wirings configured to supply a plurality of transfer clocks to said charge transfer portion, and
a read clock wiring configured to supply a read clock to said transfer gate,
wherein said charge transfer portion includes:
a transfer channel configured to be provided on said substrate, and
a transfer gate electrode configured to be provided between said plurality of transfer clock wirings and said transfer channel,
wherein said transfer gate includes:
a read channel configured to be provided on said substrate, and
a read gate electrode configured to be provided between said read clock wiring and said read channel,
wherein said substance is one of said transfer gate electrode and said read gate electrode.

3. The solid state imaging device according to claim 2, further comprising:
a first upper layer wiring configured to be provided in an upper layer arranged on said plurality of transfer clock wirings and extended in a first direction; and
a second upper layer wiring configured to be provided in said upper layer and extended along with said first upper layer wiring with a first gap therebetween,
wherein said plurality of transfer clock wirings includes:
a first clock wiring configured to be extended in a second direction perpendicular to said first direction and supply a first clock to said charge transfer portion, and
a second clock wiring configured to supply a second clock to said charge transfer portion,
wherein said transfer gate electrode includes:
a first transfer gate electrode configured to be connected to said first clock wiring, and
a second transfer gate electrode configured to be connected to said second clock wiring,
wherein said read clock wiring is extended in said second direction along with said first clock wiring with a second gap therebetween,
wherein said first clock wiring is extended along with said second clock wiring with a third gap therebetween,
wherein said read gate electrode shields a first path, through which first light passing through said first gap and said second gap passes to reach said transfer channel and said read channel, and
wherein said first transfer gate electrode and said second transfer gate electrode shield a second path, through which second light passing through said first gap and said third gap passes to reach said transfer channel and said read channel.

4. The solid state imaging device according to claim 3, wherein said read gate electrode intersects with a normal line of a surface of said substrate, said normal line passes through said first gap and said second gap, and
wherein said first transfer gate electrode or said second transfer gate electrode intersect with another normal line of said surface of said substrate, said another normal line passes through said first gap or said third gap.

5. The solid state imaging device according to claim 3, wherein said read gate electrode is composed of first material possible to absorb said first light, and
wherein said first transfer gate electrode and said second transfer gate electrode are composed of second material possible to absorb said second light.

6. The solid state imaging device according to claim 1, wherein said substance includes:
a primary color filter configured to be provided over said clock wiring group.

7. The solid state imaging device according to claim 6, further comprising:
a first upper layer wiring configured to be provided in an upper layer arranged on said plurality of transfer clock wirings and extended in a first direction; and
a second upper layer wiring configured to be provided in said upper layer and extended along with said first upper layer wiring with a first gap therebetween,
wherein said plurality of transfer clock wirings includes:
a first clock wiring configured to be extended in a second direction perpendicular to said first direction and supply a first clock to said charge transfer portion, and
a second clock wiring configured to supply a second clock to said charge transfer portion,
wherein said read clock wiring is extended in said second direction along with said first clock wiring with a second gap therebetween,
wherein said first clock wiring is extended along with said second clock wiring with a third gap therebetween, and
wherein said primary color filter is provided over said first upper layer wiring and said second upper layer wiring and absorbs at least one of first light passing through said first gap and said second gap and second light passing through said first gap and said third gap.

8. The solid state imaging device according to claim 3, wherein said first upper layer wiring, said second upper layer wiring, said first clock wiring, said second clock wiring and read clock wiring are composed of metal.

9. The solid state imaging device according to claim 3, wherein each of said first gap, said second gap and said third gap has a width in the range from 0.2 μm (micrometers) to 0.4 μm.

10. The solid state imaging device according to claim 3, further comprising:
a first bus line wiring configured to supply said first clock to said first upper layer wiring; and
a second bus line wiring configured to supply said second clock to said second upper layer wiring,
wherein said first bus line wiring supplies said first clock to said first clock wiring through said first upper layer wiring, and
wherein said second bus line wiring supplies said second clock to said second clock wiring through said second upper layer wiring.

11. The solid state imaging device according to claim 3, wherein said read clock wiring, said first clock wiring and said second clock wiring are provided in a first wiring layer, and
said first upper layer wiring and said second upper layer wiring are provided in a second wiring layer arranged on said first wiring layer.

12. The solid state imaging device according to claim 7, wherein said first upper layer wiring, said second upper layer wiring, said first clock wiring, said second clock wiring and read clock wiring are composed of metal.

13. The solid state imaging device according to claim 7, wherein each of said first gap, said second gap and said third gap has a width in the range from 0.2 μm (micrometers) to 0.4 μm.

14. The solid state imaging device according to claim 7, further comprising:
a first bus line wiring configured to supply said first clock to said first upper layer wiring; and
a second bus line wiring configured to supply said second clock to said second upper layer wiring,
wherein said first bus line wiring supplies said first clock to said first clock wiring through said first upper layer wiring, and
wherein said second bus line wiring supplies said second clock to said second clock wiring through said second upper layer wiring.

15. The solid state imaging device according to claim 7, wherein said read clock wiring, said first clock wiring and said second clock wiring are provided in a first wiring layer, and
said first upper layer wiring and said second upper layer wiring are provided in a second wiring layer arranged on said first wiring layer.

16. A method of manufacturing a solid state imaging device, wherein said solid state imaging device includes:
a light receiving portion configured to include a plurality of light receiving elements formed on a substrate,
a charge transfer portion configured to transfer electric charges supplied from said light receiving portion,
a transfer gate configured to be provided between said light receiving portion and said charge transfer portion and supply said electric charges accumulated in said light receiving portion to said charge transfer portion, and
a clock wiring group configured to include a plurality of wirings and supply a plurality of clocks for transferring said electric charges,
said method comprising:
arranging said plurality of wirings away from one another with a gap corresponding to a predetermined wavelength; and
arranging a substance capable of shielding light with a wavelength lower than said predetermined wavelength to cover said gap,
wherein said step of arranging said plurality of wirings, includes:
producing a plurality of transfer clock wirings which supplies a plurality of transfer clocks to said charge transfer portion,
producing a read clock wiring which supplies a read clock to said transfer gate,
producing a first upper layer wiring which is provided in an upper layer arranged on said plurality of transfer clock wirings and extended in a first direction, and
producing a second upper layer wiring which is provided in said upper layer and extended along with said first upper layer wiring with a first gap therebetween,
wherein said step of producing said plurality of transfer clock wirings, includes:
producing a first clock wiring which is extended in a second direction perpendicular to said first direction and supplies a first clock to said charge transfer portion, and
producing a second clock wiring which is extended in said second direction along with said first clock wiring with a second gap therebetween and supplies a second clock to said charge transfer portion,
wherein said step of producing said read clock wiring, includes:
producing said read clock wiring which is extended in said second direction and provided in parallel to said first clock wiring with a third gap therebetween, and
wherein said step of arranging said substance, includes:
forming said substance as at least one of said transfer gate electrode and said read gate electrode.

17. The method of manufacturing a solid state imaging device according to claim 16, wherein said transfer gate electrode includes:
a first transfer gate electrode configured to be connected to said first clock wiring, and
a second transfer gate electrode configured to be connected to said second clock wiring,
wherein said step of arranging said plurality of wirings, further includes:
arranging said plurality of wirings such that said read gate electrode intersects with a normal line of a surface of said substrate, said normal line passes through said first gap and said third gap and such that said first transfer gate electrode or said second transfer gate electrode intersect with another normal line of said surface of said substrate, said another normal line passes through said first gap or said third gap.
